(19) United States
(12) Patent Application Publication
(10) Pub. No.: US 2012/0061837 A1
(43) Pub. Date: Mar. 15, 2012

(54) METHOD OF MANUFACTURING SEMICONDUCTOR DEVICE AND SEMICONDUCTOR DEVICE

(75) Inventors: Daina INOUE, Mie-ken (JP); Minori KAJIMOTO, Kanagawa-ken (JP)

(73) Assignee: Kabushiki Kaisha Toshiba, Tokyo (JP)

(21) Appl. No.: 13/230,106

(22) Filed: Sep. 12, 2011

(30) Foreign Application Priority Data
Sep. 15, 2010 (JP) 2010-206920

(51) Int. Cl. H01L 23/48; H01L 21/768

(52) U.S. Cl. 257/741; 438/675; 257/774; 257/E21.586; 257/E23.011

(57) ABSTRACT

In a method of manufacturing a semiconductor device according to an embodiment, an etching stopper, an oxide film and a mask material are formed. A trench pattern is formed in the mask material. The oxide film is etched to form the trench pattern therein by using the mask material having the trench pattern formed therein as a mask. The etching stopper is etched until the etching stopper is penetrated to form the trench pattern therein, by using the oxide film having the trench pattern formed therein as a mask. A Cu film is formed to be filled in the trench pattern formed in the etching stopper and the oxide film and to cover the top surface of the oxide film. CMP is performed on the Cu film and the oxide film until the top surface of the etching stopper serving as a stopper is exposed.

### CROSS-REFERENCE TO RELATED APPLICATION

The present application claims the benefit of priority from Japanese Patent Application No. 2010-206920, filed on Sep. 15, 2010, the content of which is incorporated herein in its entirety.

### FIELD

Embodiments of the invention relate to a method of manufacturing a semiconductor device and the semiconductor device.

### BACKGROUND

Damascene process is one of processes to form wirings. In the damascene process for forming a Cu wiring layer, for example, Cu is filled in trenches of the Cu wiring layer. A semiconductor substrate after the filling of Cu is subjected to CMP (Chemical Mechanical Polishing) down to the top of an interlayer film. Further, additional CMP is performed in consideration of local unevenness on the wiring layer and local variations in the polishing amount.

Nonetheless, in the damascene process, variations in the polishing rate (polishing amount) of the CMP may be reflected on the thicknesses of the Cu wirings in some cases.

For this reason, a semiconductor device manufacturing method that allows the formation of a Cu wiring layer with a smaller thickness variation has been desired.

### BRIEF DESCRIPTION OF THE DRAWINGS

FIGS. 1A to 1G are cross-sectional views schematically showing a method for manufacturing a semiconductor device according an embodiment and are presented in the sequence of the procedure.

FIG. 2 is a schematic cross-sectional view showing a different semiconductor device manufactured by a method of manufacturing a semiconductor device according to an embodiment.

FIG. 3 is a schematic cross-sectional view showing a different semiconductor device manufactured by a method of manufacturing a semiconductor device according to an embodiment.

FIG. 4 is a schematic cross-sectional view showing a different semiconductor device manufactured by a method of manufacturing a semiconductor device according to an embodiment.

FIGS. 5A and 5B are cross-sectional views showing some steps in a method of manufacturing a semiconductor device according to a comparative example.

### DETAILED DESCRIPTION

According to embodiments, in each method of manufacturing a semiconductor device, an etching stopper film having a thickness corresponding to a desired thickness of each Cu wiring is formed above a semiconductor substrate. A silicon oxide film is formed on the etching stopper film. A mask material is formed on the silicon oxide film. A trench pattern corresponding to the shape of the Cu wiring is formed in the mask material through lithography. By using the mask material having the trench pattern formed therein as an etching mask, the silicon oxide film is etched to form the trench pattern therein.

Hereinbelow, methods of manufacturing a semiconductor device according to some embodiments will be described in detail with reference to the accompanying drawings. It should be noted that these embodiments are not intended to limit the invention.

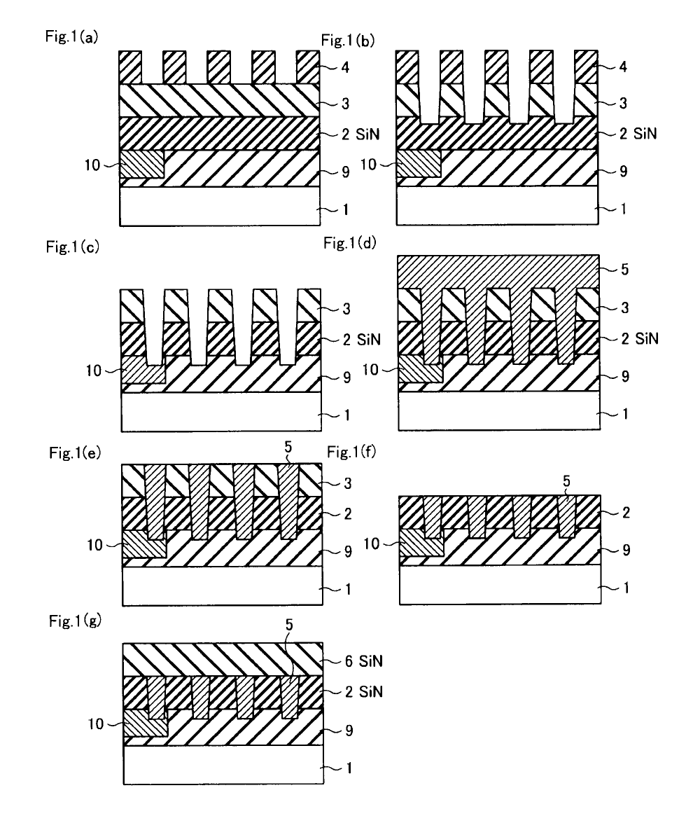

FIGS. 1A to 1G are cross-sectional views schematically showing a method for manufacturing a semiconductor device according the embodiment and are presented in the sequence of the procedure.

First, as shown in FIG. 1A, a silicon oxide film layer 9 having for example a lower layer wiring 10 formed therein is formed on a semiconductor substrate 1. An etching stopper film 2 having a film thickness corresponding to the thickness of each of later-formed Cu wirings is formed on the silicon oxide film layer 9. This film thickness corresponding to the thickness of the later-formed Cu wiring can be described as a thickness necessary for securing the thickness of the Cu wiring. A silicon oxide film 3 and a mask material 4 are formed in this order on the etching stopper film 2. A trench pattern corresponding to the shape of the to-be-formed Cu wiring are formed in the mask material 4 through lithography. Here, the etching stopper film 2 is made of SiN, for example. The mask material 4 is a resist material, a hard mask material, or the like.

Then, as shown in FIG. 1B, by using the mask material 4 having the trench pattern formed therein as an etching mask, the silicon oxide film 3 is etched through RIE to form the trench pattern therein. An etching gas containing C and F such as CF4 or C4F6 is used as the etching gas in this event. The trenches reach the etching stopper film 2 by the end of the etching.

Then, as shown in FIG. 1C, the mask material 4 is removed. By using the silicon oxide film 3 as an etching mask, the etching stopper film 2 made for example of SiN is etched through RIE to form the trench pattern therein. An etching gas containing C and F or containing C and H such as CF4, C4H8, or C4F6 is used as the etching gas in this event. The trenches penetrate through the etching stopper film 2 and reach the lower layer wiring 10 by the end of the etching.

Thereafter, as shown in FIG. 1D, a Cu film 5 is deposited to completely fill the trenches thus formed and also cover the silicon oxide film 3. Then, CMP is performed down to the top surface of the silicon oxide film 3 to obtain a state shown in FIG. 1E.

Then, as shown in FIG. 1F, CMP is performed on the silicon oxide film 3 and the Cu film 5. In this event, the etching stopper film 2 is used as a CMP stopper. That is, the CMP ends when the top surface of the etching stopper film 2 is exposed. Accordingly, by controlling the film thickness of the etching stopper film 2, the film thickness of the Cu film 5 can be controlled. Thereafter, as shown in FIG. 1G, a cap material 6 made for example of SiN is formed.

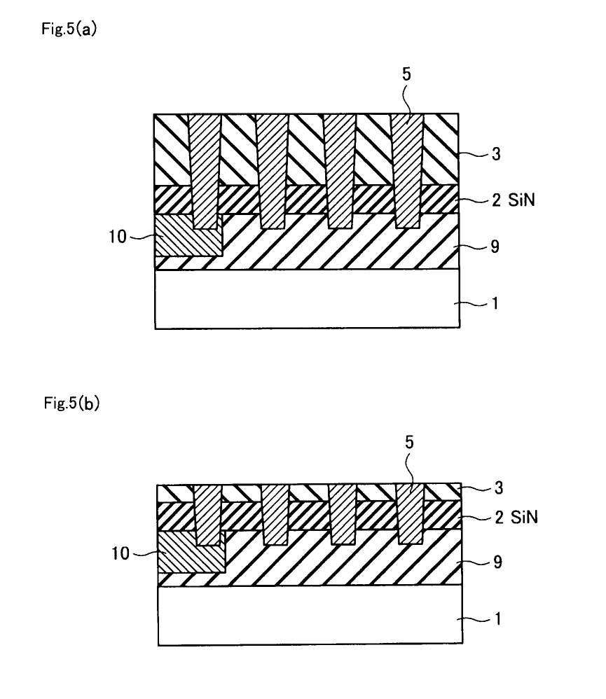

Here, for the purpose of comparison, FIGS. 5A and 5B show cross-sectional views showing some steps in a method for manufacturing a semiconductor device according to a comparative example. FIGS. 5A and 5B are presented in the sequence of the procedure. FIG. 5A is a view equivalent to the step of FIG. 1E of the embodiment in which the Cu is removed through CMP until the oxide film as a buried interlayer film is exposed.

As shown in FIG. 5A, in a semiconductor device of the comparative example, the film thickness of the etching stopper film 2 is a film thickness of a film as a stopper of RIE. That is, the film thickness of the etching stopper film 2 is smaller than the film thickness of each Cu wiring to be formed. Thus, when CMP is performed down to a desired wiring thickness shown in FIG. 5B, the CMP is performed with no border, i.e., with no stopper. The CMP effective period is determined based on the duration of the CMP, or the like. Since the film thickness removed by the CMP is controlled based on time, it is difficult to reduce variations in the film thicknesses of the Cu wirings as compared to the embodiment. With the miniaturization of semiconductor elements, it is becoming more and more difficult to fill Cu in a process of forming Cu wirings. An influence of variations in the thicknesses of the Cu wirings is large especially when a sufficient wiring thickness cannot be secured.

According to the embodiment, the etching stopper film 2 used as a stopper of the RIE in the formation of the wiring trenches is also used as a stopper of the CMP in the formation of the wirings. Specifically, the bottom surface of the etching stopper film 2 functions as an etching stopper of the RIE, and after the RIE, the top surface of the etching stopper film 2 functions as a stopper of the CMP. Accordingly, the Cu wiring film 5 can be formed with its film thickness accurately controlled to a desired thickness with the help of the film thickness of the etching stopper film 2 in the trench formation stage.

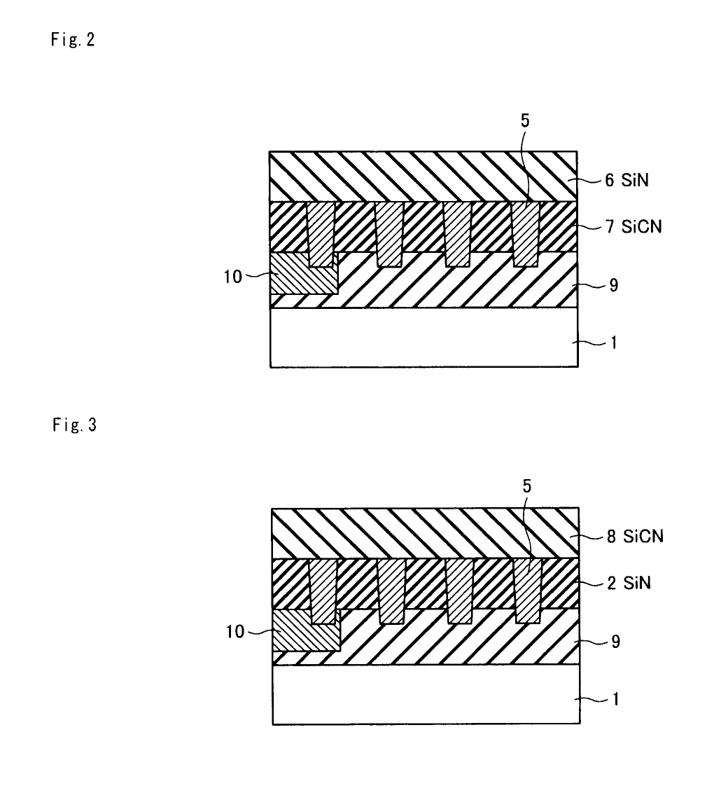

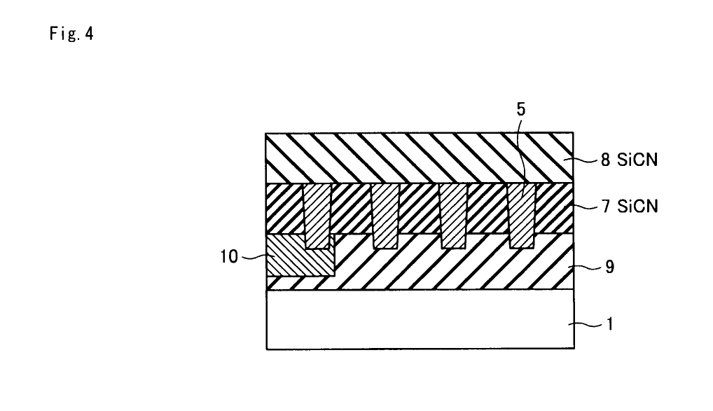

Meanwhile, in the above-described embodiment, the etching stopper film 2 and the cap material 6 are described as being made of SiN. However, as shown in FIGS. 2 to 4, any one or both of the etching stopper film 2 and the cap material 6 may be formed as a SiCN etching stopper film 7 and a SiCN cap material 8 containing SiCN that is lower in relative permittivity than SiN. In a case of using the SiCN etching stopper film 7 and the SiCN cap material 8, the interwiring capacitance can be reduced as compared to the case of the above-described embodiment in which SiN covers the Cu wirings almost entirely. As a result, the wiring delay of each Cu wiring can be reduced. Note that in the cases of FIGS. 2 and 4 using the SiCN etching stopper film 7, an etching gas containing C and F or containing C and H such for example as CF4, C4H8, or C4F6 is used as the etching gas in RIE in a step equivalent to FIG. 1C. The other steps remain substantially the same as those of the above-described embodiment.

Further, instead of Cu wirings, it is possible to use wirings obtained by a different damascene process, e.g., Al wirings, W wirings, or wirings including both.

Hereinabove, exemplary embodiments of the invention are described with reference to specific examples. However, the embodiments of the invention are not limited to these specific examples. For example, one skilled in the art may similarly practice the invention by appropriately selecting specific configurations of components such as semiconductor substrates, Cu wirings, etching stopper layers Si oxide layers, etc., included in semiconductor devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all methods for manufacturing semiconductor memory devices and semiconductor memory devices practicable by an appropriate design modification by one skilled in the art based on the methods for manufacturing the semiconductor memory devices and the semiconductor memory devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method of manufacturing a semiconductor device comprising:
forming an etching stopper film above a semiconductor substrate, the etching stopper film having a thickness corresponding to a desired thickness of a Cu wiring;
forming a silicon oxide film on the etching stopper film;
etching the silicon oxide film to form therein a trench pattern corresponding to a shape of the Cu wiring;
etching the etching stopper film until penetrating the etching stopper film to form the trench pattern therein, by using the silicon oxide film having the trench pattern formed therein as an etching mask;
forming a Cu film that is filled in the trench pattern formed in the etching stopper film and the silicon oxide film and covers a top surface of the silicon oxide film; and
performing CMP on the Cu film and the silicon oxide film until a top surface of the etching stopper film serving as a CMP stopper is exposed.

2. The method of manufacturing a semiconductor device according to claim 1, further comprising depositing a cap material as an insulating film after performing the CMP.

3. The method of manufacturing a semiconductor device according to claim 2, wherein the cap material is any one of SiN and SiCN.

4. The method of manufacturing a semiconductor device according to claim 1, wherein the etching stopper film is made of any one of SiN and SiCN.

5. The method of manufacturing a semiconductor device according to claim 1, wherein
the semiconductor substrate includes a lower layer wiring, and
in the formation of the Cu film, the Cu film is so formed that the Cu film filled in the trench pattern is connected to the lower layer wiring.

6. The method of manufacturing a semiconductor device according to claim 1, wherein
a mask material is formed on the silicon oxide film,
the trench pattern is formed in the mask material through lithography, and
the silicon oxide film is etched by using the mask material having the trench pattern formed therein as an etching mask.

7. The method of manufacturing a semiconductor device according to claim 1, wherein any one of Al and W is used instead of the Cu.

8. A semiconductor device comprising:
an etching stopper film formed above a semiconductor substrate where a circuit is formed;
a Cu wiring filled in a trench provided in the etching stopper film; and
a cap material provided on the etching stopper film and the Cu wiring, wherein
the Cu wiring is formed by
forming the etching stopper film above the semiconductor substrate, the etching stopper film having a thickness corresponding to a desired thickness of the Cu wiring,
forming a silicon oxide film on the etching stopper film,
etching the silicon oxide film to form therein a trench pattern corresponding to a shape of the Cu wiring;
etching the etching stopper film until penetrating the etching stopper film to form the trench pattern therein, by using the silicon oxide film having the trench pattern formed therein as an etching mask;
forming a Cu film that is filled in the trench pattern formed in the etching stopper film and the silicon oxide film and covers a top surface of the silicon oxide film; and
performing CMP on the Cu film and the silicon oxide film until a top surface of the etching stopper film serving as a CMP stopper is exposed.
